(19) United States
(12) Patent Application Publication
(10) Pub. No.: US 2025/0076216 A1
(43) Pub. Date: Mar. 6, 2025

(54) METHOD AND APPARATUS FOR DETECTING DEFECTS IN A PACKAGE

(71) Applicant: Applied Materials, Inc., Santa Clara, CA (US)

(72) Inventors: Venkatakaushik VOLETI, San Jose, CA (US); Yun-Ching CHANG, Pleasanton, CA (US); Dan XIE, Mountain View, CA (US); Gregory KIRK, Pleasanton, CA (US); Mehdi VAEZ-IRAVANI, Los Gatos, CA (US)

(21) Appl. No.: 18/799,653

(22) Filed: Aug. 9, 2024

Related U.S. Application Data
(60) Provisional application No. 63/536,366, filed on Sep. 1, 2023.

(51) Int. Cl. G01N 21/95; G01N 21/47; H01L 21/66; H01L 23/00

(52) U.S. Cl. CPC G01N 21/9505; G01N 21/4738; H01L 22/12; H01L 24/80; G01N 2201/06113; G01N 2201/062; H01L 2224/8012; H01L 2224/80895; H01L 2224/80896

(57) ABSTRACT

An optical inspection system for pre-bonding inspection includes a stage having a surface on which a sample to be inspected is placed, the surface of the sample having at least parts with a two dimensional (2D) periodic pattern which may include defects, an optical head including optics, a dark-field illuminator configured to illuminate the surface of the sample at an first angle, wherein the first angle is an oblique angle, a bright-field illuminator configured to illuminate the surface at a second angle, a dark-field collection path, a bright-field collection path, and a sensor configured to detect light transmitted from the dark-field illuminator, scattered at the surface of the sample, collected by the optical head, and relayed through the dark-field collection path, and light transmitted from the bright-field illuminator, reflected at the surface of the sample, and relayed through the bright-field collection path.

### CROSS-REFERENCE TO RELATED APPLICATIONS

This application claims priority to U.S. Provisional Application Ser. No. 63/536,366 filed Sep. 1, 2023, which is herein incorporated by reference in its entirety.

### FIELD

Embodiments described herein generally relate to a semiconductor device fabrication process, and more particularly, to pre-bonding inspection in a chip-to-substrate hybrid bonding process.

### BACKGROUND

Next-generation chips can no longer rely solely on transistor shrinkage as a key driver of computing power, as transistor critical dimensions (CDs) have already approached their physical lower limit of the size of a few atoms. Meanwhile demand for high-performance, low-power chips continues to grow, driven in part by advances in artificial intelligence (AI), augmented reality (AR), virtual reality (VR), Internet of things (IoT), and other markets. Advanced packaging technologies have emerged to address this demand by combining chips of multiple types (e.g., memory, logic) onto a single integrated system, resulting in low-latency components with highly efficient power management. However, as the design parameters for these back-end-of-the-line processes grow ever more stringent, the process tolerances required to enable them grows as well. In many instances, a process can bond multiple, fully-manufactured chiplets onto a single substrate prior to testing. A defect in even one bonding step can result in failure of the entire package, an expensive and time-consuming loss. Identifying such point defects (e.g., particles, pits, scratches, and bumps) prior to bonding is crucial to yield improvement. For this reason, high-throughput optical inspection has the potential to be a key enabler of next-generation advanced packaging technologies.

While such optical inspection techniques presented herein are relevant for all patterned wafers, inspection tools for advanced packaging need to be compatible with a range of sample types—be they fully intact wafers or smaller singulated chiplets. We use chip-to-substrate (C2S) hybrid bonding as a relevant example of a packaging technique which uses both intact wafers and chiplets as inputs to its processing steps. Alternative packaging techniques such as wafer-to-wafer bonding can similarly benefit from the approaches described herein. C2S hybrid bonding is chip-stacking technique in which pre-diced chiplets are precisely fused onto a larger substrate. Unlike previous bonding techniques, metallic interconnects (e.g., copper) are embedded both in dielectric layers (e.g., SiOₓ) of a chiplet and in dielectric layers on a substrate to which the chiplet is bonded. When brought into contact, the dielectric layers of the chiplet and the substrate weakly bond with one another almost instantly. A subsequent high-temperature annealing step is then required to fuse the metallic interconnections, as well as strengthen the bond between the dielectric layers.

The presence of point defects such as particles, chips, cracks, or excessive topographical variations on surfaces of the chiplet and/or the substrate, adversely affect bond quality and give rise to post-bonding defects. These post-bonding defects generally manifest as air gaps of various sizes that impede proper interconnect formation, adversely impact yield, and result in costly wastage of fully manufactured chiplets/substrate. This wastage is particularly severe in use cases where a single substrate may host multiple chiplets (either stacked side-by-side on the substrate, or one-atop-another). However, a pre-bonding inspection to identify such small point defects (e.g., hundreds of nanometers) has been a challenge since optical signals from small point defects are buried in large optical signals from features (e.g., metallic interconnects) in certain geometrical patterns formed in the large substrate having a width or diameter of about 300 mm.

Accordingly, there is a need for a pre-bonding inspection system that can effectively detect small pre-bonding point defects while reducing the obscuring effect of signals generated from geometrical patterns formed on a substrate.

### SUMMARY

Embodiments of the present disclosure provide an optical inspection system for pre-bonding inspection. The optical inspection system includes a stage having a surface on which a sample to be inspected is placed, the surface of the sample having a two dimensional (2D) periodic pattern and defects, an optical head including optics, a dark-field illuminator configured to illuminate the surface of the sample at a first angle, wherein the first angle is an oblique angle, a bright-field illuminator configured to illuminate the surface at a second angle, a dark-field collection path, a bright-field collection path, and a sensor configured to detect light transmitted from the dark-field illuminator, scattered at the surface of the sample, collected by the optical head, and relayed through the dark-field collection path, and light transmitted from the bright-field illuminator, reflected at the surface of the sample, and relayed through the bright-field collection path.

Embodiments of the present disclosure also provide an optical inspection system for pre-bonding inspection. The optical inspection system includes a stage having a surface on which a sample to be inspected is placed, the surface of the sample having a two dimensional (2D) periodic pattern and defects, an optical head including an optics, a first dark-field illuminator configured to illuminate the surface of the sample at a first oblique angle, a second dark-field illuminator configured to illuminate the surface of the sample at a second oblique angle, a bright-field illuminator configured to illuminate the surface at a bright-field illumination angle, a dark-field collection path, a bright-field collection path, and a sensor configured to detect light transmitted from the first dark-field illuminator and the second dark-field illuminator, scattered at the surface of the sample, collected by the optical head, and relayed through the dark-field collection path, and light transmitted from the bright-field illuminator, reflected at the surface of the sample, and relayed through the bright-field collection path.

Embodiments of the present disclosure further provide a method of chip-to-substrate hybrid bonding. The method includes performing a pre-bonding inspection process on a substrate die having metallic bond pads, and a chiplet having metallic bond pads, including generating an optical image of point defects on a surface of the substrate die by an optical inspection system having a bright-field illumination mode, and a dark-field imaging mode, and inspecting the generated optical image, wherein inspecting the generated optical image comprises at least one of determining a location of at least one of the point defects on the surface of the substrate die based on the optical image of the point defects on the surface of the substrate die, and determining a location of at least one of the point defects on the surface of the chiplet based on the optical image of the point defects on the surface of the chiplet.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 depicts a process flow diagram of a method of a chip-to-substrate hybrid bonding process, according to one or more embodiments of the present disclosure.

FIGS. 2A, 2B, and 2C are cross-sectional views of a substrate die and a chiplet, corresponding to various states of the method 100 of FIG. 1.

FIGS. 3A, 3B, 3C, 3D, and 3E depict types of samples in which defects and particles formed thereon can be detected by an optical inspection system according to the embodiments described herein.

FIG. 4 is a schematic view of an optical inspection system, according to one or more embodiments of the present disclosure.

FIG. 5A is a schematic view of an oblique angle of illumination from dark-field illuminators that is useful for one or more of the methods described herein.

FIGS. 5B and 5C depict example optical images of a surface of a sample.

FIG. 6 is a schematic view of optical Fourier transformation that is useful for one or more of the methods described herein.

To facilitate understanding, identical reference numerals have been used, where possible, to designate identical elements that are common to the figures. It is contemplated that elements and features of one embodiment may be beneficially incorporated in other embodiments without further recitation. In the figures and the following description, an orthogonal coordinate system including an X-axis, a Y-axis, and a Z-axis is used. The directions represented by the arrows in the drawings are assumed to be positive directions for convenience. It is contemplated that elements disclosed in some embodiments may be beneficially utilized on other implementations without specific recitation.

### DETAILED DESCRIPTION

The embodiments described herein provide systems and methods for performing an optical inspection process to detect small point defects on a chiplet and/or a substrate die to which the chiplet is bonded. The system described herein has two distinct imaging modes, a dark-field imaging mode and a bright-field imaging mode, combined in a single system. These two imaging modes are simultaneously used to inspect distinct pattern types within a single substrate die.

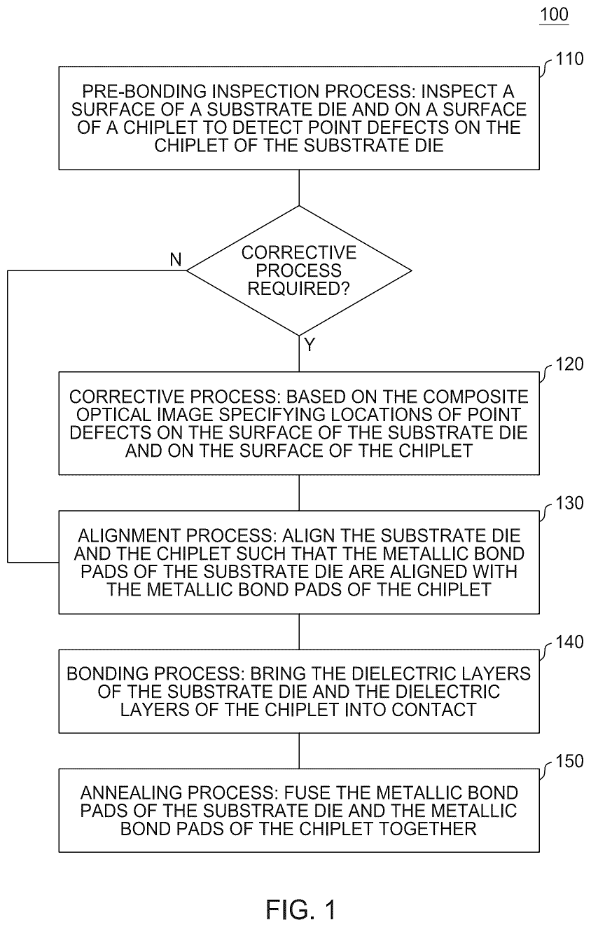

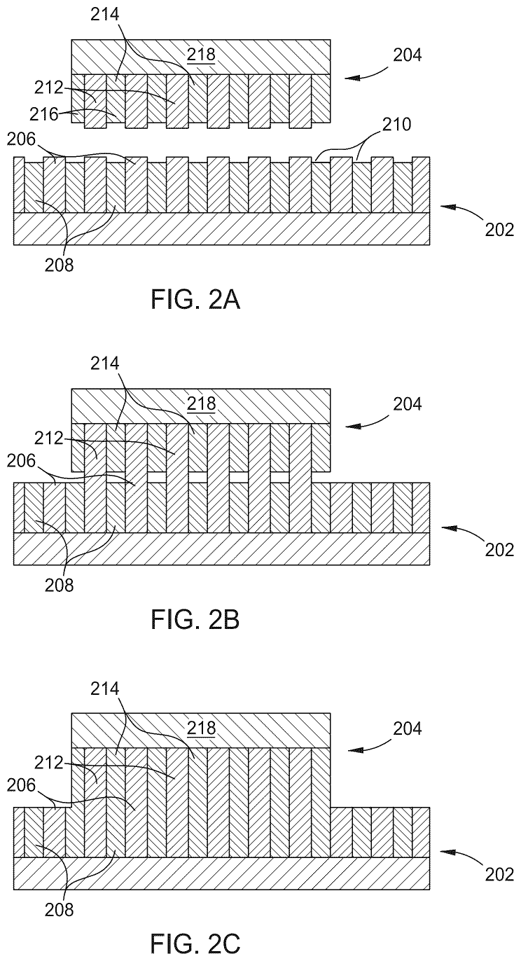

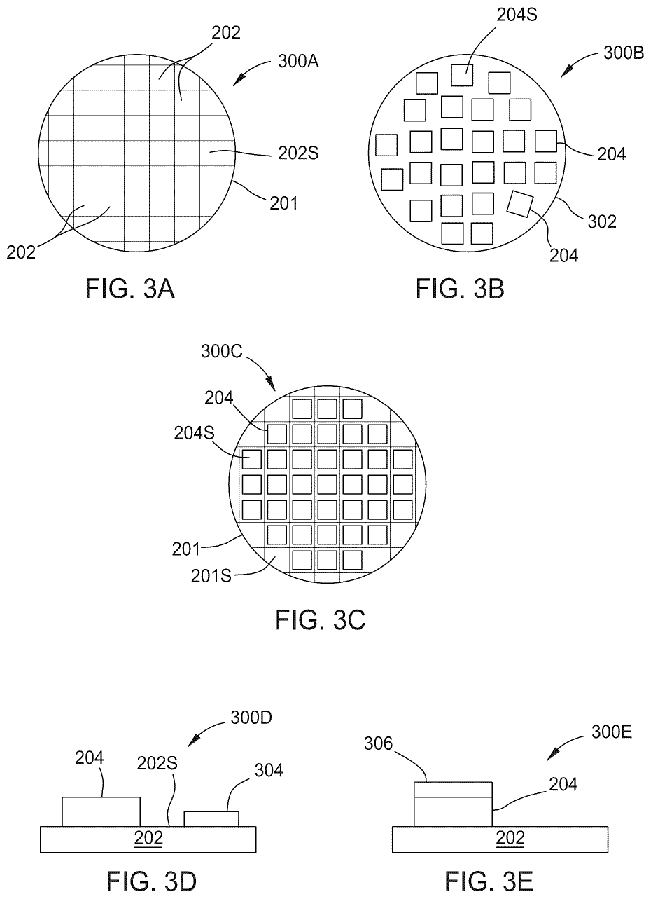

FIG. 1 depicts a process flow diagram of a method 100 of a chip-to-substrate hybrid bonding process, according to one or more embodiments of the present disclosure. FIGS. 2A, 2B, and 2C are cross-sectional views of a substrate die 202 and a chiplet 204 (e.g., a die singulated from another substrate), corresponding to various states of the method 100. In some cases, the substrate die 202 is one portion of a larger substrate 201 (FIG. 3A) that includes a plurality of substrate die 202 formed therein, wherein the larger substrate 201 can include, for example, a 300 mm, 450 mm, 550 mm, or larger square or round substrate.

As shown in FIG. 2A, the substrate die 202 may include metallic bond pads 208, having features 210, embedded within a dielectric layer 206. The chiplet 204 may include a dielectric layer 212 and metallic bond pads 214, having features 216, embedded within the dielectric layer 212. The dielectric layers 206 and 212 may be formed of silicon dioxide (SiO₂), for example. In one example, the metallic bond pads 208 and the metallic bond pads 214 may be circular or rectangular, and are commonly substantially formed of copper.

The method 100 begins with block 110, in which a pre-bonding inspection process is performed on a surface of the substrate die 202 and on a surface of the chiplet 204, to detect point defects, such as chips, cracks, scratches, organic residues, or other particles positioned on the chiplet 204, and excessive topological variations on the chiplet 204 or the substrate die 202.

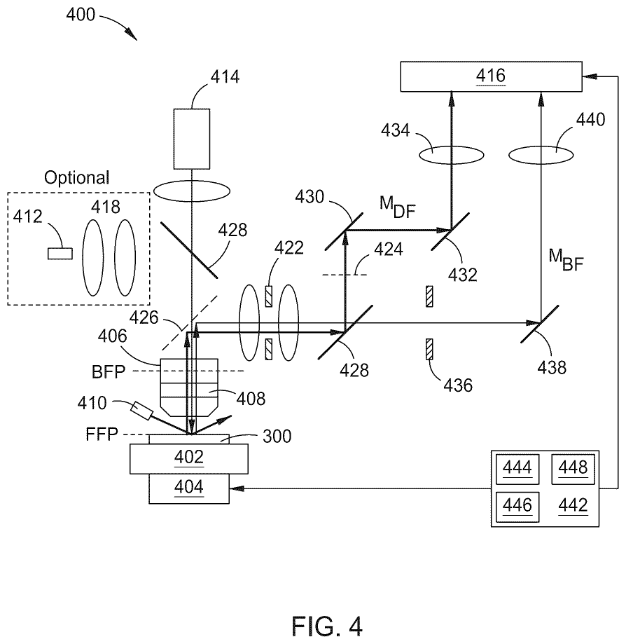

The pre-bonding inspection process includes generating an optical image of a surface of a sample (e.g., a surface of the substrate die 202, a surface of the chiplet 204) by an optical inspection system, such as the optical inspection system 400 (FIG. 4), having a bright-field illumination (or reflected-light) mode, and a dark-field imaging mode, in which an optical signal from features in a two dimensional (2D) periodic pattern, such as the metallic bond pads 208 on the substrate die 202 and the metallic bond pads 214 on the chiplet 204, can be eliminated or reduced. The optical image of point defects of the surface of the sample is then reconstructed to generate a map of point defects on the surface of the sample, specifying locations of the point defects on the surface of the sample. The generated map includes information relating to the relative position of the defects found on or within the sample based on pixel coordinate data generated by the optical sensor based on the received optical signal. In some embodiments, a system controller generates a 2D map of the defects found on or within a sample. The generated 2D map contains the position information (e.g., X-Y position information) for the various defects, which can then be used to perform a corrective process.

In block 120, a corrective process is performed based on the optical image specifying locations of point defects on the surface of the substrate die 202 and on the surface of the chiplet 204. The corrective process may include adding or modifying a pre-cleaning process on the surface of the substrate die 202 and/or the surface of the chiplet 204 to remove particles prior to a boding process, reducing bonding pressures for scratched chiplets in a bonding process to reduce chiplet cracking, depositing additional gapfill material on the surface of the substrate die 202 and/or the surface of the chiplet 204 after a bonding process to ensure coverage of varying chiplet heights, or halting the chip-to-substrate hybrid bonding process, and removing the chiplet 204 for further steps of the chip-to-substrate hybrid bonding process. The corrective process may further include a feed backwards into potentially defective processes outside of a bonder (e.g., CMP, dicing) as a function of wafer location, or time, creating metrics for initial setup, tool qualification and tool-to-tool matching, prompting tool maintenance and re-qualification as a function of increased defectivity over time.

In block 130, an alignment process is performed to align the substrate die 202 and the chiplet 204 such that the metallic bond pads 208 of the substrate die 202 are aligned with the metallic bond pads 214 of the chiplet 204.

In block 140, as shown in FIG. 2B, a bonding process is performed to bring the surface of the substrate die 202 and the surface of the chiplet 204 into contact. When brought into contact, the dielectric layer 206 of the substrate die 202 and the dielectric layer 212 of the chiplet 204 weakly bond to one another.

In block 150, as shown in FIG. 2C, an annealing process is performed to fuse the metallic bond pads 208 of the substrate die 202 and the metallic bond pads 214 of the chiplet 204 together. A high temperature anneal step fuses the metallic bond pads 208 and the metallic bond pads 214, as well as strengthen the bonding of the dielectric layer 206 of the substrate die 202 and the dielectric layer 212 of the chiplet 204. Electrical circuits (not shown) on the bottom of the substrate die 202 are then connected to electrical circuits 218 formed in the chiplet 204.

During the chip-to-substrate hybrid bonding process, the presence of point defects on the chiplet 204 or a substrate die 102, affect fidelity of the chip-to-substrate hybrid bonding and give rise to post-bonding defects. The post-bonding defects generally manifest as air gaps that impede proper interconnect formation or form broken circuits, which will adversely impact device yield, and result in the costly need to scrap the fully manufactured chiplet/substrate dies. The created waste is particularly severe in use cases where a single substrate die 202 may host multiple chiplets (either stacked side-by-side on the substrate, or one-atop-another).

In block 160, a post-bonding inspection process is performed. The post-bonding inspection process may include one or more of the process steps described in relation to block 110, which is discussed above and described in further detail below. The post-bonding inspection process includes generating an optical image of bonded chiplets 204 or substrate die 102 disposed within at least a portion of a package assembly, which can contain multiple chiplets, memory, interposers, and other ICs, by use of an optical inspection system, such as the optical inspection system 400 (FIG. 4).

The embodiments described herein provide an optical inspection system that can effectively detect point defects while eliminating or reducing the effect of the optical signal received from background (e.g., optical signals from the substrate having features in a periodic pattern formed thereon), such that the point defects can be detected, addressed and/or resolved during a chip-to-substrate hybrid bonding process. The processes described herein can be used to detect, address and resolve the presence of point defects in the pre-bonded package before the point defects can adversely affect bond quality and/or give rise to post-bonding defects that will affect device yield.

FIGS. 3A, 3B, 3C, 3D, and 3E depict types of samples in which defects and particles formed thereon can be detected by an optical inspection system according to the embodiments described herein.

FIG. 3A depicts a first type sample 300A to be inspected, which includes a substrate 201 that includes a plurality of substrate dice 202 to which chiplets 204 can be bonded.

FIG. 3B depicts a second type sample 300B to be inspected, which includes singulated and unbonded chiplets 204 on a carrier 302. The carrier 302 may be a tape frame. The chiplets 204 have been diced or sawed, and mounted to the carrier 302, to be transferred to the substrate die 202 during a bonding process. Although the carrier 302 sufficiently holds the chiplet 204 during a singulation process, the chiplets 204 are not always positioned in an aligned manner due to the singulation process which destroys the lithography-defined alignment, and further due to the flexibility of the carrier 302. Thus, some of the chiplets 204 may be skewed relative to each other. In one example, the chiplets 204 are misaligned relative to each other in a plane that is parallel to a top surface 204S of the chiplets 204. However, in some cases the top surfaces 204S of the chiplets 204 are misaligned relative to each other, wherein the misalignment can include a spacing in the X, Y and Z directions misalignment and also an angular misaligned such as a pitch, yaw and roll angular orientation misalignment. For example, as the carrier 302 flexes, top surfaces 204S of the chiplets 204 vary in height relative to each other.

FIG. 3C depicts a third type sample 300C to be inspected, which includes singulated chiplets 204 bonded to a top surface 201S of the substrate 201 (shown in FIG. 3A).

FIG. 3D depicts a fourth type sample 300D to be inspected, which includes a substrate die 202 having a singulated chiplet 204 bonded thereon, and a chiplet 304 having a different height from the chiplet 204 to be bonded to the substrate die 202. In some cases, as shown in FIG. 3D, the top surfaces 204S of the singulated chiplets 204 and a top surface 202S of the substrate die 202 present a substantial height difference that must be overcome when optically scanning top surfaces of the third type sample 300C.

FIG. 3E depicts a fifth type sample 300E to be inspected, which includes a singulated chiplet 204 bonded to the substrate die 202 and another singulated chiplet 306 bonded to the singulated chiplet 204.

### Optical Inspection System Overview

FIG. 4 is a schematic view of an optical inspection system 400 to inspect a surface of a sample, such as the sample 300, according to one or more embodiments of the present disclosure. The optical inspection system 400 has two distinct imaging modes, a dark-field imaging mode and a bright-field imaging mode, combined in a single system. These two imaging modes are simultaneously used to inspect two (distinct or the same) pattern types within a single substrate die.

The optical inspection system 400 includes a stage 402 having a surface on which a sample 300 having a two dimensional (2D) periodic pattern and defects to be inspected is placed, a motion assembly 404, an optical head 406 including a lens 408 (e.g., a microscope objective lens) having a sample field-of-view (FOV) focused on a portion of a surface of the sample 300, a dark-field illuminator 410, a gray-field illuminator 412, a bright-field illuminator 414, a dark-field collection path M_{DF}, a bright-field collection path M_{BF}, a sensor 416, such as a time delay integration (TDI) linear sensor, and a controller 442. A sensor 416 is generally a method of using a charge-coupled device (CCD) or complementary metal-oxide-semiconductor (CMOS) as an image sensor for capturing images of an object that is moved relative to the sensor. The process utilizes the time-delay integration of the accumulation of cumulative exposures of the same object as it is moving linearly relative to the sensor. The sensor 416 detects light transmitted from the dark-field illuminator 410 or the gray-field illuminator 412, scattered at the surface of the sample 300, collected by the optical head 406, and relayed through the dark-field collection path M_{DF}, and light transmitted from the bright-field illuminator 414, scattered at the surface of the sample 300, collected by the optical head 406, and relayed through the bright-field collection path M_{BF}. A sample 300 may include a substrate die 202 and chiplets 204 and 304 bonded on a surface of the substrate die 202.

The dark-field imaging mode is used to inspect un-patterned areas (e.g., regions with a pure dielectric layer) and patterned areas with periodic structures on a surface of a sample. Light scattered from the surface using darkfield of the sample 300 is to be optically Fourier filtered and imaged onto the sensor 416. The bright-field imaging mode is used to inspect patterned areas as well. Light reflected from the surface in bright-field imaging mode of the sample 300 is not to be optically Fourier filtered, but is imaged onto a separate spot upon the same sensor 416.

### Combination of Bright-Field Illumination and Dark-Field Illumination

In operation, the surface of a sample 300, such as a sample 300A, 300B, 300C, 300D, or 300E, is illuminated simultaneously by the dark-field illuminator 410 or the gray-field illuminator 412 and the bright-field illuminator 414. The resulting reflected and scattered lights from the surface of the sample 300 are simultaneously collected by the same optical head 406, relayed separately via a dark-field collection path M_{DF} and a bright-field collection path M_{DF}, and mapped onto separate isolated portions upon the same sensor 416. Thus, images by the dark-field imaging mode and by the bright-field imaging mode are simultaneously acquired.

The images acquired by the bright-field imaging mode need to satisfy the Nyquist criterion to avoid aliasing artifacts, which may interfere with analysis algorithms specific to the bright-field imaging mode. In other words, the bright-field imaging mode has an optical point spread function. This image resolution needs to be properly sampled by the sensor 416, which requires an appropriate camera pixel size, PixelSize sensor, to be determined according to:

$${PixelSize}_{obj} = {PixelSize}_{sensor} / OpticalMag , \\ {PixelSize}_{obj} = \frac{λ}{NA} * 0.2653 \sim \frac{λ}{4 NA} \\ λ \sim {PixelSize}_{obj} * 4 * NA$$

where OpticalMag is an optical magnification of the optical inspection system 400 from the substrate die 202 to the sensor 416, NA is the numerical aperture, and A is the wavelength of the bright-field illumination.

The sensor 416 continuously acquires data upon a moving sample, synchronizing acquisition of successive rows of data with the movement of the stage 402 in desired direction. As a result, images collected by the sensor 416 have two independent spatial dimensions, a first dimension measured along the length of the sensor 416 in a first direction, and a second dimension along the movement direction (e.g., second direction) of the stage 402. The pixel size along the first dimension is purely a function of the optical magnification, while the pixel size along the second dimension is a function of the optical magnification and scanning speed of the stage 402.

In practice, the dark-field illumination uses the shortest possible wavelength to detect nanoscale defects (e.g., at lower UV wavelengths). In some embodiments, a UV wavelength provided from a dark-field illumination source can be between 200 nanometers (nm) and 600 nm. If the bright-field illumination uses wavelength as short as that of the dark-field illumination, the pixel size at the object will need to become incredibly small to satisfy the Nyquist criterion, which in turn will result in several disadvantageous tradeoffs, such as lower throughput, higher data, and lower signal/pixel ratio. Thus, in the embodiments described herein in, wavelength longer than the dark-field illumination is used in the bright-field imaging mode, to satisfy the Nyquist criterion without any tradeoffs related to optical magnification and throughput. In some embodiments, a wavelength provided from a bright-field illumination source can be between 300 nanometers (nm) and 700 nm. Furthermore, different wavelengths between the two imaging modes ensure their separability onto different portions upon the sensor 416.

### Dark-Field Modality

### Illumination

In the dark-field imaging mode, the surface of the sample 300 is illuminated at an oblique angle by a coherent light source, the dark-field illuminator 410 or the gray-field illuminator 412. Dark-field illumination is particularly sensitive to defects on edges of chiplets, and particles on surfaces and edges of a sample. Dark-field illumination is also sensitive to large un-wanted height variations at edges of the chiplets which can cause significant artifacts near the edges of the sample.

The dark-field illuminator 410 and the gray-field illuminator 412 may be each a laser having a short wavelength (e.g., at lower UV wavelengths) to maximize cross-sections on small sized defects. In some embodiments, the laser light is introduced by way of a multi-mode or single-mode fiber.

The laser illuminates a large area upon the sample. This area fills the equivalent of an image of the sensor 416, back-projected through our optical system on top of our sample. For example, if the magnification is 10× and the sensor 416 is 10×1 mm², the laser illuminates an area of at least 1×0.1 mm².

Laser light for dark-field imaging can be delivered via a single or multi-mode fiber. The latter method of illumination facilitates large amounts of power (≥1 W) to be directed towards the sample 300 without significantly increasing the complexity, footprint of the laser, or cost. Speckle related variations due to the multi-modality of the laser source can either be addressed via a scrambling mechanism, or ignored due to the imaging system's tolerance of such artifacts. In some other embodiments, the dark-field illuminator 410 and the gray-field illuminator 412 are each a free-space (non-fiber coupled) laser. The laser light may be polarized or un-polarized.

In some embodiments, the laser may have a circular beam shape having a large spot size (e.g., hundreds of microns to mm in diameter). Since a circularly shaped laser beam has a plane wavefront, divergence of the laser beam needs to be minimized. In some other embodiments, the laser may have a rectangular beam shape (e.g., length of mm along a longitudinal (long) direction, and width of tens to hundreds of microns along the transverse (short) direction). Divergence of the laser beam along the longitudinal (long) direction similarly needs to be minimized, while divergence along the transverse (short) direction is adjusted to control width of the laser beam along the transverse (short) direction. Laser beam can be shaped by the known beam-shaping optics, such as beam expansion with sets of spherical/aspheric lenses, or creation of beam line by cylindrical lenses.

### Uni-Directional Dark-Field Illumination

The surface of the sample 300 may be uni-directionally illuminated at one oblique angle. In some embodiments, the light transmitted from the dark-field illuminator 410 is delivered from outside of the collection aperture of the lens 408. In some other embodiments, the light from the gray-field illuminator 412 is delivered from within the collection aperture of the lens 408 via an optical relay 418, to project the laser light appropriately through the objective lens and shape the laser light at the sample into a circular/rectangular/elliptical shape.

### Multi-Directional Dark-Field Illumination

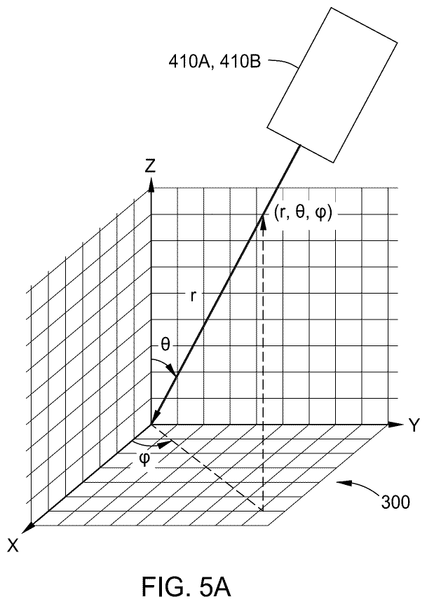

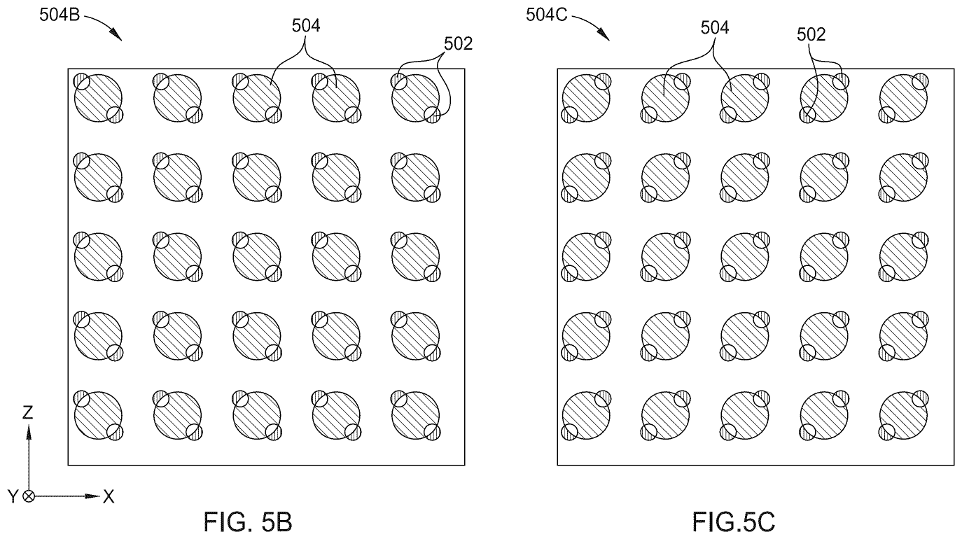

The surface of the sample 300 may be illuminated by a dark-field illuminator 410 that includes a multi-directional illuminator that is configured to illuminate a sample at two or more oblique angles, such as by use of two dark-field illuminators 410A and 410B. The oblique angles of illumination for each of the two dark-field illuminators 410A and 410B can be described along a polar angle θ and an azimuthal angle φ, where the surface of the sample 300 is in the X-Y plane, as shown in FIG. 5A.

In one example, the oblique angles (the polar angle θ_{A} and the azimuthal angle φ_{A}) for the dark-field illuminator 410A, and the oblique angles (the polar angle θ_{B} and the azimuthal angle φ_{B}) for the dark-field illuminator 410B are related to each other as θ_{A}=θ_{B} and φ_{A}=180°+φ_{B}. In this example, lights from the two dark-field illuminators 410A and 410B are delivered to the surface of the sample 300 from opposite directions and nearly identical Fourier transformed patterns are generated at the back focal plane BFP of the lens 408 by the two dark-field illuminators 410A and 410B.

When this technique is applied to an array of circular bond pads disposed in a 2D periodic pattern f(x, y) with a circular symmetry (e.g., the periodic array of metallic bond pads 208) on a substrate, an optical image includes a brightness distribution akin to a dipole 502 that are formed at the edges of each individual metallic bond pad 208, as shown in FIGS. 5B and 5C. The orientation of the dipole 502 is related to the oblique angle (e.g., azimuthal φ angle) of illumination. In the optical images 504B and 504C found in FIGS. 5B and 5C, respectively, the array of circular metallic bond pads 208 that would be seen by an epi-illumination are shown by large circles 504 for reference to the position of the metallic bond pads 208. It should be noted that an optical image of point defects on the surface of the sample 300 is not dependent on the oblique angle of illumination. The optical image 504B and the optical image 504C can then be combined, by the controller 442, to generate a composite optical image of point defects on the surface of the sample, specifying location of the detected point defects on the surface of the sample. By combining these two separate optical images 504B and 504C that were taken with different directions of illumination (for example, taking the minimum value at each pixel in the optical images 504B and 504C, or taking the product of optical images 504B and 504C), by the controller 442, the optical signal generated by the periodic pattern f(x, y) (e.g., the array of circular metallic bond pads 208) can be reduced, while maintaining the optical signal generated by point defects. Alternative filtering techniques can be—for examplethresholding on any linear super-position of the per-pixel signal for 504B/504C. One could also create a 2D vectorial representation for each pixel consisting of the intensity of each image, wherein a certain area within this 2D phase space represents “defectivity” or “normality” for specific types of patterns. The composite optical image generated can then be used to generate a map of the point defects found on the surface of the sample, which specifies the locations of one or more point defects found on the surface of the sample substrate. The generated map will include information relating to the relative position of the defects found on or within the sample based on pixel coordinate data found within the optical images generated by the optical sensor. The generated maps can then be used to take a corrective action relating to the sample as discussed above.

These imaging techniques are useful when imaging the fourth type sample 300D, shown in FIG. 3D, or the fifth type sample 300E, shown in FIG. 3E, which includes singulated chiplets 204 bonded to the top surface 202S of the substrate die 202. Height of the bonded chiplets 204 results in a shadow onto the substrate die 202 when illuminated. The light from the opposite direction will then be able to illuminate the shadowed region on the substrate die 202.

In another example, the oblique angles (the polar angle θ_{A} and the azimuthal angle φ_{A}) for the dark-field illuminator 410A, and the oblique angles (the polar angle θ_{B} and the azimuthal angle φ_{B}) for the dark-field illuminator 410B are related to each other as θ_{A}=θ_{B} and φ_{A}=90°+θ_{B}. In this example, lights from the two dark-field illuminators 410A and 410B are delivered to the surface of the sample 300 from orthogonal directions. The azimuthal angle φ can be changed by using stationary separate illuminators (e.g., the dark-field illuminator 410) for each angle, rotating the sample 300, or physically moving the illumination assembly (e.g., the dark-field illuminator 410).

This orthogonal bi-directional dark-field illumination is useful in the following three scenarios. First, in the fourth type sample 300D shown in FIG. 3D, where the lateral distance between the two chiplets 204 and 304 is small, the shadows cast by the chiplets 204, 304 when illuminating from either the left or right direction (i.e. 180 degree illumination shift) will not permit illumination of the space in between. Second, in an alternative type of pattern with large and/or aperiodic structures, for which bright-field mode will not have sufficient sensitivity. By combining images illuminated from these two orthogonal or opposing directions, the background of these structures can be reduced. Third, in linear structures, such as scribe lines, vernier scales, combs, which lie along a wafer axis. When one of these structures lies along the X-axis of the wafer, whereas illumination is along the Y-direction, the signal from the structure will not be reduced. However, when illuminating along the X direction (i.e. a 90 degree shift), the signal will be reduced.

In some embodiments, the dark-field illuminator 410 is an incoherent light source, such as a light emitting diode (LED), which can be used to inspect aperiodic structures when illuminated at an oblique angle. In this case, light scattered from the surface of the sample 300 is not to be optically Fourier filtered.

In some other embodiments, the dark-field illuminator 410 is a ring-dark-field with an incoherent source, such as a LED and a conduit (e.g., a fiber, a liquid light guide), or an LED array and shaping optics.

### Collection

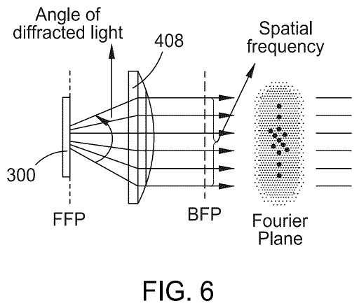

The surface of the sample 300 is placed at a front focal plane (FFP) of the lens 408. As shown in FIG. 6, any electric field distribution at the front focal plane FFP of the lens 408 is Fourier transformed and projected onto the back focal plane (BFP) of the lens 408. Because many high performance lenses have BFP's embedded within the body of the lens itself, an optical lens train can be used to relay the BFP to an area with the mechanical access necessary for further filtering. Thus, an angle of light incident upon and scattered from the surface of the sample 300 (at the front focal plane FFP of the lens 408) is related to a spatial frequency of light at the back focal plane BFP of the lens 408. A steeper illumination angle (e.g., closer to a normal angle) upon the surface of the sample 300 corresponds to a higher spatial frequency projected onto the back focal plane BFP of the lens 408. Similarly, a steeper detection angle (e.g., closer to a normal angle) of light from the surface of the sample 300 corresponds to a higher spatial frequency detected at the back focal plane BFP of the lens 408. As a result, a larger numerical aperture NA (or lower focal length) corresponds to a larger cone of light collected by the lens 408, leading to higher spatial frequencies and crisper images. The numerical aperture NA of the lens 408 therefore determines the upper and lower bound of the spatial frequencies detected from the surface of the sample 300.

### Fourier Filtering

The dark-field collection path M_{DF} s separated from the bright-field collection path M_{BF} by use of a dichroic mirror 428. It includes a field stop 422 and a mask 424 on an optical plane conjugate to the back focal plane BFP of the lens 408. A uni-directional laser light (having a plane wave front) is scattered at discrete angles from patterned areas with periodic structures (e.g., the metallic bond pads 214 or the dielectric layer 206) on a surface of a sample. The Fourier transform of periodic structures, therefore, preferentially concentrates the intensity of light on specific portions of spatial frequency space at the Fourier plane. In contrast, light scattered by a particle, a point defect, or surface roughness more broadly distributes energy across the entire Fourier plane. By using this difference, the mask 424 can preferentially filter light scattered from the periodic structures. The mask 424 may be a number of adaptive optical components such as transmissive or reflective spatial light modulators, digital micro-mirror devices and ferroelectric liquid crystal displays, to preferentially block light reflected from periodic structures at the Fourier plane based on known variations in the periodic pattern. This allows the optical inspection system 400 to flexibly accommodate a range of periodic patterns and alignment orientations of a substrate die. Alternatively, the mask 424 may be static patterned mechanical filters (e.g., metal, film on glass) that can be rotated into and out of the Fourier plane as needed for known specific periodic patterns formed on a substrate die that is to be inspected. A field stop 422 defines precisely the region of the object that is imaged onto the sensor 416. As a result, it creates specific regions on the sensor 416 that are used for bright-field and dark-field images, without any possibility of cross-talk between them.

The dark-field collection path M_{DF} further includes one or more mirrors 430, 432 and an imaging lens 434 to relay the filtered light to a portion of the sensor 416.

### Bright-Field Modality

### Illumination

In the bright-field imaging mode, the surface of the sample 300 is illuminated at a substantially right angle normal to the surface of the sample 300 by an incoherent light source, the bright-field illuminator 414. It is introduced to the optical system by way of a splitting mirror 426.

The bright-field illuminator 414 may be a light emitting diode (LED), a light bulb, or a flash lamp, and may be tandem with a set of wavelength filters. Wavelengths are selected to satisfy the Nyquist criteria as discussed above. Multiple wavelengths can be optionally installed.

In some embodiments, the bright-field illuminator 414 can be directly coupled to the optical inspection system 400, or brought into the proximity with the optical inspection system 400 by way of a conduit (e.g., a fiber, a liquid light guide). Fiber conduits can help lower footprint of the optical inspection system 400, especially when using multi-wavelength light sources. The bright-field illuminator 414 is coupled to a set of optics designed to fill the FOV of the lens 408.

### Collection

The bright-field collection optical path M_{BF} does not rely on Fourier filtering. A pupil stop 436 on the bright-field collection path M_{BF} is separated from the field stop 422 on the dark-field collection path M_{DF}, such that the masking system (i.e. the mask 424) on the dark-field collection path M_{DF} does not interfere with the bright-field light reflected by the surface of the sample 300. The pupil stop 436 and the field stop 422 perform two different functions. The pupil stop 436 limits the NA of the lens (and, therefore, the resulting resolution) of the collection optical path M_{BF}. The field stop 422, on the other hand, is used to ensure that bright-field and dark-field images are well separated on the sensor 416, with no possibility of cross talk.

The bright-field collection path M_{BF} further includes a mirror 438 and an imaging lens 440 to relay the bright-field light reflected by the surface of the sample to a separate portion of the sensor 416.

In some embodiments, the bright-field illuminator 414 uses two or more wavelengths. If two wavelengths are on opposite sides of a cutoff wavelength λ_{c} of the LP dichroic mirrors 428, imaging by both bright-field wavelengths can be performed simultaneously if the dark-field imaging mode is turned off. However, imaging by any two or more bright-field wavelengths on the same side of cutoff wavelength λ_{c} would need to be performed sequentially. It should be noted that this type of multi-wavelength imaging is useful to microscopic review of defects after initial detection. Furthermore, individual materials on a substrate die have different spectral properties (e.g., the reflectance spectrum of copper versus silicon) and these multiple imaging modes are useful in differentiating structures that would otherwise look alike using only one imaging mode.

These multiple imaging modes (e.g., the dark-field imaging mode and the bright-field imaging mode) are used simultaneously, with spectral and spatial crosstalk reduced. Light from the two imaging modes is collected by the same lens 408 at the sample 300, and the dark-field collection path M_{DF} and the bright-field collection path M_{BF} have a shared portion. However, the two imaging modes are spatially separated before mapped to different parts of the same sensor 416.

The distinction between the two imaging modes is one of wavelengths. The bright-field imaging mode is subject to the Nyquist criterion, and thus is a longer wavelength is used, such that the LP dichroic mirror 428 (shown in FIG. 4) is used to separate the multiple imaging modes relative to one another. The spectral separation of the two imaging modes is ensured by light source selection, selection of spectral filters to confine the bandwidth of each imaging mode, and these dichroic mirrors 428.

After the spatial separation with the dichroic mirrors 428, light in the bright-field imaging mode gets redirected towards a set of optics (e.g., mirrors, lenses) that relay the image onto a portion of the sensor 416. The dark-field imaging mode goes through the Fourier filtering, and then goes through a separate set of optics which relay the filtered image onto a separate portion of the same sensor 416.

However, because the two imaging modes share a single sensor 416, the field stop 422 is further used to limit overlap between the two images on the sensor 416 in order to avoid cross-contamination. This is done using a field stop (422 within FIG. 4), which limits the spatial extent of the both images on the sensor 416.

### Motion Assembly

The motion assembly 404 can move the stage 402 in multiple axes to allow complete scanning of a surface of the sample 300. In some embodiments, the stage 402 is a 4-axis stage (i.e., X, Y, Z, φ motion), where the Z axis corresponds to the transverse direction normal to the surface of the sample 300, the X and Y axes are lateral directions parallel to the surface of the sample 300, and the e corresponds to rotation about the Z axis. Alternatively, the optical inspection system 400 can contain an autofocus compensatory mechanism independent of the stage 402. An image of the surface of the sample 300 projected onto the sensor 416 may be parallel to one of the lateral axes (X or Y), while the motion of the other axes may be synchronized to successive exposures of the sensor 416.

### Process Tool Integration

The controller 442 is in communication with the motion assembly 404 and can cause the motion assembly 404 to move the stage 402, for example, back and forth in the X-direction to continuously scan the surface of the sample 300, and in the Z-direction to maintain a distance between the lens 408 and the surface of the sample 300 within a focusing range of the optical head 406. The controller 442 can also communicate with the optical head 406 to facilitate in adjusting illumination, focus, and other optical assembly parameters. The controller 442 may also receive and store raw images from the sensor 416 and process the stored raw images (e.g., combine the stored raw images) and/or provide control the sensor 416 as needed. The controller 442 may directly control the optical inspection system 400, or alternatively control other controllers (e.g., computers) associated with the optical inspection system 400. In operation, the controller 442 enables data collection and feedback from the optical inspection system 400 to optimize performance of the optical inspection system 400 and to control the process flows according to the methods described herein.

The controller 442 generally includes a central processing unit (CPU) 444, a memory 446, and a support circuit 448. The CPU 444 may be any form of a general-purpose computer processor that can be used in an industrial setting. The one or more processors can include central processing units, graphics processing units, accelerators, etc. The support circuit 448 is coupled to the CPU 444 and may comprise a cache, clock circuits, input/output subsystems, power supplies, and the like. Software routines, such as the process flows according to the methods as described herein may be stored in the memory 446 and, when executed by the CPU 444, transform the CPU 444 into a specific purpose computer as the controller 442. The memory 446 includes main memory for storing instructions (e.g., programs/software routines) for the one or more processors to execute or data for the one or more processors to operate on. For example, the memory includes random access memory (RAM), or any other suitable form of non-volatile, solid-state memory, or read-only memory. The software routines may also be stored and/or executed by a second controller (not shown) that is located remotely from the optical inspection system 400.

It should be noted that an optical inspection system, such as the optical inspection system 400, along with the associated motion control system, such as motion assembly 404, can be packed into a chamber in a multi-chamber semiconductor processing tool. This chamber can be integrated as part of a longer set of streamlined processes, or alternatively can be a separate stand-alone system with a separate factory interface within the processing tool.

As discussed above, the sensor 416 can be used in coordination with the motion assembly 404 to continuously and/or rapidly acquire bright-field and dark-field data upon a moving sample by synchronizing the acquisition of successive rows of data collected by the sensor 416 with the movement of the stage 402 in at least one direction, such as the X, Y, Z or φ direction. As a result, images collected by the sensor 416 as a function of time have two independent spatial dimensions, a first dimension measured along the length of the sensor 416 in a first direction, and a second dimension along the movement direction (e.g., second direction) of the stage 402, which by use of the bright-field and dark-field illumination techniques described herein, collection techniques described herein, and software running on the controller 442 can be used to analyze and preferentially detect the coordinate positions of any defects found on the surface of a sample versus periodic patterns formed in a sample.

Therefore, one or more of the embodiments described herein provide systems and methods for pre-bonding inspection to identify point defects on a surface of a chiplet and/or a surface of a substrate die to which the chiplet is to be bonded. In the systems described herein, a surface of a sample (e.g., a chiplet, a substrate die, or a substrate die with a chiplet bonded thereto) is illuminated by coherent light from an optical fiber (or, alternatively, by free-space propagating collimated coherent radiation) and optical signals from features (such as metallic bond pads) in a geometrical pattern (e.g., a circular pattern) on a substrate die (e.g., 300 mm wafer) is eliminated or reduced, and thus signals from small defects (e.g., hundreds of nanometers) is enhanced. A map of small defects on the surface of the sample generated from the optical image can be used to identify locations of such small defects and determine corrective actions to perform during a chip-to-substrate hybrid bonding process. The system described herein has two distinct imaging modes, a dark-field imaging mode and a bright-field imaging mode, combined in a single system. These two imaging modes are simultaneously used to inspect distinct pattern types within a single substrate die.

While the foregoing is directed to embodiments of the present disclosure, other and further embodiments of the disclosure may be devised without departing from the basic scope thereof, and the scope thereof is determined by the claims that follow.

1. An optical inspection system for pre-bonding inspection, comprising:
a stage having a surface on which a sample to be inspected is placed, the surface of the sample having at least a portion which consists of a two dimensional (2D) periodic pattern and point defects;
an optical head including optics;
a dark-field illuminator configured to illuminate the surface of the sample at an first angle, wherein the first angle is an oblique angle;
a bright-field illuminator configured to illuminate the surface at a second angle;
a dark-field collection path;
a bright-field collection path; and
a sensor configured to detect:
light transmitted from the dark-field illuminator, scattered at the surface of the sample, collected by the optical head, and relayed through the dark-field collection path; and
light transmitted from the bright-field illuminator, reflected at the surface of the sample, and relayed through the bright-field collection path.

2. The optical inspection system of claim 1, wherein the dark-field illuminator comprises a laser.

3. The optical inspection system of claim 1, wherein the light transmitted from the dark-field illuminator is delivered from outside of a collection aperture of the optics.

4. The optical inspection system of claim 1, wherein the light collected from the dark-field illuminator is delivered from within a collection aperture of the optics.

5. The optical inspection system of claim 1, wherein the bright-field illuminator comprises a light emitting diode (LED) and is configured to illuminate the surface of the sample at the second angle which is substantially normal to the surface of the sample.

6. The optical inspection system of claim 1, wherein the dark-field illuminator uses wavelength that is shorter than the wavelength of the bright-field illuminator.

7. The optical inspection system of claim 1, wherein the dark-field collection path comprises:
a filter configured to Fourier filter the light transmitted from the dark-field illuminator, scattered at the surface of the sample, and collected by the optical head.

8. An optical inspection system for pre-bonding inspection, comprising:
a stage having a surface on which a sample to be inspected is placed, the surface of the sample having at least a region consisting of a two dimensional (2D) periodic pattern and point defects;
an optical head including an optics;
a first dark-field illuminator configured to illuminate the surface of the sample at a first oblique angle;
a second dark-field illuminator configured to illuminate the surface of the sample at a second oblique angle;
a bright-field illuminator configured to illuminate the surface at a bright-field illumination angle;
a dark-field collection path;
a bright-field collection path; and
a sensor configured to detect:
light transmitted from the first dark-field illuminator and the second dark-field illuminator, scattered at the surface of the sample, collected by the optical head, and relayed through the dark-field collection path; and
light transmitted from the bright-field illuminator, reflected at the surface of the sample, and relayed through the bright-field collection path.

9. The optical inspection system of claim 8, wherein the first dark-field illuminator and the second dark-field illuminator each comprise a laser.

10. The optical inspection system of claim 8, wherein lights from the first dark-field illuminator and the second dark-field illuminator are delivered to the surface of the sample from opposite directions.

11. The optical inspection system of claim 8, wherein lights from the first dark-field illuminator and the second dark-field illuminator are delivered to the surface of the sample from orthogonal directions.

12. The optical inspection system of claim 8, wherein the bright-field illuminator comprises a light emitting diode (LED) and is configured to illuminate the surface of the sample at the bright-field illumination angle which is substantially normal to the surface of the sample.

13. The optical inspection system of claim 8, wherein the first dark-field illuminator and the second dark-field illuminator each use wavelength that is shorter than wavelength of the bright-field illuminator.

14. The optical inspection system of claim 8, wherein the dark-field collection path comprises:
a filter configured to Fourier filter the light transmitted from the first dark-field illuminator and the second dark-field illuminator, scattered at the surface of the sample, and collected by the optical head.

15. A method of chip-to-substrate hybrid bonding, comprising:
performing a pre-bonding inspection process on a substrate die having metallic bond pads, and a chiplet having metallic bond pads, comprising:
generating an optical image of point defects on a surface of the substrate die by an optical inspection system having a bright-field illumination mode, and a dark-field imaging mode; and
inspecting the generated optical image, wherein inspecting the generated optical image comprises at least one of:
determining a location of at least one of the point defects on the surface of the substrate die based on the optical image of the part of surface of substrate die which includes point defects; and
determining a location of at least one of the point defects on the surface of the chiplet based on the optical image of the point defects on the surface of the chiplet.

16. The method of claim 15, further comprising:
performing a corrective process based on the generated optical image of the point defects on the surface of the chiplet or the generated optical image of the point defects on the surface of the substrate die.

17. The method of claim 16, further comprising:
performing an alignment process, to align the metallic bond pads of the substrate die and the metallic bond pads of the chiplet; and
performing a bonding process, to bring the surface of the substrate die and the surface of the chiplet into contact.
